(19) United States
(12) Patent Application Publication
(10) Pub. No.: US 2025/0321275 A1
(43) Pub. Date: Oct. 16, 2025

(54) OPERATING DEVICE WITH FUNCTIONAL MONITORING OF THE SWITCHING-STATE DETECTION, ASSOCIATED USE AND METHOD

(71) Applicant: Preh GmbH, Bad Neustadt a.d. Saale (DE)

(72) Inventors: Johannes JEGER, Nüdlingen (DE); Martin MÖLTER, Bad Neustadt/Lebenhan (DE)

(73) Assignee: Preh GmbH, Bad Neustadt a.d. Saale (DE)

(21) Appl. No.: 19/175,799

(22) Filed: Apr. 10, 2025

(30) Foreign Application Priority Data
Apr. 12, 2024 (EP) 24169986.7

(51) Int. Cl. G01R 31/327; G01R 19/25

(52) U.S. Cl. CPC G01R 31/3277; G01R 19/2503

(57) ABSTRACT

An operating device has a first microcontroller, having at least one first measurement input, is adapted to detect a measurement potential at the first measurement input and to output an associated detection result that depends on the respective measurement potential; a voltage source having a supply voltage; a resistor network to apply the supply voltage, wherein the first measurement input is connected to a first tap; at least one switching element integrated in the resistor network, the switching state of the switching element is changed by operation by an operator; wherein the resistor network is adapted such that a different switching potential at the first measurement input is assigned to the respective switching state; a second microcontroller, superordinate to the first microcontroller is adapted to receive the respective detection result from the first microcontroller and to output said detection result to a superordinate control unit.

### TECHNICAL FIELD

The present disclosure relates to an operating device which has a switching element, such as a switch or button, which is able to be operated by an operator, and a first microcontroller for ascertaining the respective switching state of the switching element.

### BACKGROUND

These microcontrollers typically have a digital input, or an input which converts from analog to digital, in order to infer the switching state of the switching element on the basis of the potential present at the input. ISO 26262 stipulates the technical effort with which the operational safety of the operating device (“functional safety”) can be ensured depending on how safety-relevant the vehicle function that is to be controlled by the operating device is. This relates, for example, to the microcontroller that is to be used. This microcontroller is comparatively expensive and complex in design, in particular if it has a plurality of inputs, for example for ascertaining the switching states of a plurality of switching elements, and may be difficult to procure in the event of a shortage caused by a crisis. Being stuck in the detection range is a known error mode of microcontrollers in a motor vehicle. Other errors relate to the problems that there are values outside the detection range, low values outside the detection range, and an offset between the actual value (nominal value) and the measured value. A microcontroller that is stuck in the detection range has failed in such a way that it generates a constant signal which lies within the normal detection range; this is particularly problematic and difficult to detect. A conventional plausibility diagnosis makes provision to compare the measured values of a first microcontroller on the basis of a first signal with the measured values of a second microcontroller on the basis of a second signal, wherein the first and second signals are correlated signals, in order to determine whether one of the first and second microcontrollers is stuck in the detection range by comparing the absolute difference between the signals with an error limit. If the absolute difference is too large, at least one of the measured values is interpreted such that the associated microcontroller is stuck in the detection range and is faulty. In practice, the error limit for this type of plausibility diagnosis is set quite high in order to minimize false indication of an error by the diagnosis. Consequently, this type of plausibility diagnosis is limited to diagnosing microcontrollers which have a significant offset value, or those which are stuck in the detection range at a value far away from the nominal value, so that this type of plausibility diagnosis has a detection range which is similar to a diagnosis outside the detection range and is limited in sensitivity to that of this diagnosis.

### SUMMARY

Against this background, there was a need for an operating device in which functional monitoring is reliably ensured, in particular the event of the microcontroller being stuck in the detection range can be reliably detected, and an ISO 26262-compliant functional monitoring can be implemented comparatively simply and thus cost-effectively. The disclosed embodiments provide an operating device that enables reliable functional monitoring. Moreover, advantageous use and a method for functional monitoring are further disclosed. Attention is drawn to the fact that the features listed individually in the patent claims can be combined with one another in any technologically expedient manner and reveal further configurations of embodiments disclosed herein. Additional characterization and specification of the disclosed embodiments are provided by the description, especially in conjunction with the figures.

The present disclosure relates to an operating device which has a first microcontroller having at least one first measurement input, which is designed to detect a measurement potential respectively present at the first measurement input and to output a respectively associated detection result which is dependent on the respective measurement potential. According to the present disclosure, provision is furthermore made for a voltage source having a supply voltage predefined by two supply potentials.

The device according to the disclosed embodiments further has a resistor network to which the supply voltage is applied, wherein the first measurement input of the first microcontroller is electrically conductively connected to a first tap at the resistor network.

According to the present disclosure, provision is made for at least one switching element integrated in the resistor network, the switching state of which at least one switching element, out of at least two switching states, is changed from one switching state to the respective other switching state by operation, contact and/or actuation by an operator. For example, the switching element is an electromechanical switch or button, or a capacitive or resistive sensor-based switching element.

According to the present disclosure, the resistor network is designed such that a different switching potential present at the first measurement input is assigned to the respective switching state, wherein preferably at least one switching potential differs from the supply potentials, more preferably all of the switching potentials differ from the supply potentials.

According to the present disclosure, provision is furthermore made for a second microcontroller superordinate to the first microcontroller, which second microcontroller is designed to receive the respective detection result from the first microcontroller and to output said detection result to a superordinate control unit. Superordinate means that the second microcontroller is not only interposed on the way of the data transmission of the detection result from the first microcontroller to the control unit but also decides on the transfer to the control unit in dependence on functional monitoring triggered by it.

According to the present disclosure, provision is additionally made for an active component which is able to be controlled by the first microcontroller and/or by the second microcontroller, is integrated into the resistor network and is controlled, for example by influencing the resistor network, such that an interference potential having a predefined time characteristic is present as the measurement potential present at the first measurement input. For example, the active component is an electromechanical switch or a semiconductor-based switching element, such as a transistor. For example, an additional branch in the resistor network is switched by the active component. The predefined time characteristic means, for example, the time characteristic in terms of absolute value; preferably at least the frequency of the time characteristic of the interference potential is predefined. For example, the predefined time characteristic of the interference potential is stored as a default in the first microcontroller or in the second microcontroller. Depending on where the default is stored, in the first or second microcontroller, the detection result of the first microcontroller can be compared with the default. In one configuration, the default relating to the time characteristic of the interference potential is stored in the second microcontroller and is transmitted only to the first microcontroller for controlling the active component, while the subsequent comparison of the detection result resulting from the control is transmitted to the second microcontroller after transmission, in order to assume from this, by comparing the two, in the event that the two do not sufficiently correspond to one another, a non-detection of the time characteristic of the interference potential and thus a failure of the first microcontroller.

According to the present disclosure, the second microcontroller is designed to at least temporarily prevent a subsequent output of the detection result to the superordinate control unit in the event of a non-detection of the predefined time characteristic of the interference potential by the first microcontroller during the associated control of the active component and thus assuming a failure of the first microcontroller. Due to the design according to the disclosed embodiments, a failure of the first microcontroller, but in particular the event of it being stuck in the detection range, can be reliably detected; in particular microcontroller-based detection can be easily transformed into an ISO 26262-compliant design by simple extension with superordinate monitoring by a further microcontroller.

Preferably, the predefined characteristic of the interference potential is periodic and has a frequency which is higher than a minimum switching frequency of the switching element.

Preferably, at least the first measurement input of the first microcontroller is designed as a digital input.

In order to increase the interference sensitivity with respect to electromagnetic interference, the first microcontroller according to one preferred configuration has a second measurement input which is electrically conductively connected to a second tap, which is different from the first tap, in the resistor network and is designed to determine the detection result from a difference in potential between the measurement potential respectively present at the first measurement input and second measurement input. More preferably, the second measurement input and the first measurement input are designed as digital inputs. For example, the first and second taps are performed on a different branch of the resistor network in each case.

Preferably, provision is made for two switching elements, the switching states of which, out of at least two switching states, are changed by actuation by an operator, wherein the switching elements are integrated in different branches of the resistor network.

Preferably, an active component is provided for each switching element, wherein the active components are controlled in parallel.

Preferably, provision is made for the first switching element to be in an open state, i.e. for the associated branch of the resistor network to be interrupted, while the interference potential having the predefined time characteristic is present at the first measurement input of the first microcontroller. More preferably, provision is made for the first and second switching elements to be in an open state, i.e. for the associated branches of the resistor network to be interrupted, while the interference potential having the predefined time characteristic is present at the first measurement input and at the second measurement input of the first microcontroller.

Preferably, the second microcontroller is designed to report a fault to the superordinate control unit.

The present disclosure further relates to the use of the operating device in one of the previously described embodiments in a motor vehicle for the functional monitoring of safety-relevant switching-state detection.

The present disclosure further relates to a method for the functional monitoring of switching-state detection, having the following steps. In a provision step, an operating device in one of the previously described embodiments is provided. In a control step of the method according to the present disclosure, the active component is controlled in such a way that an interference potential having a predefined time characteristic is present as the measurement potential present at the first measurement input. In a simultaneous or subsequent step, according to the present disclosure the otherwise provided output and transmission of the detection result from the second microcontroller to a superordinate control unit are suspended if the interference potential has not been previously detected by the first microcontroller during the control of the active component effected by the second microcontroller. This allows a failure of the microcontroller, but in particular the event of it being stuck in the detection range, to be reliably detected.

### BRIEF DESCRIPTION OF THE DRAWINGS

Other advantageous aims, benefits and implementations of the various embodiments disclosed herein are more clearly apparent from the detailed description of a specific exemplary embodiment in connection with the appended drawing, in which:

FIG. 1 illustrates an exemplary embodiment of an electronic circuit diagram of the device according to an embodiment.

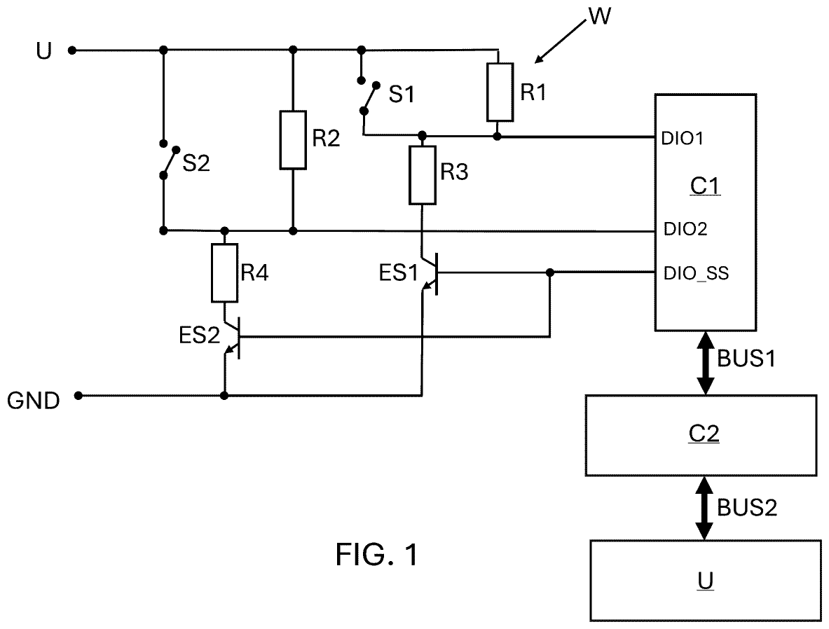

### DETAILED DESCRIPTION

The present disclosure relates to an operating device 1 which has a first microcontroller C1 having a digital input as a first measurement input DIO1 and a further digital input as a second measurement input DIO2, which are each designed to detect a measurement potential respectively present at the first measurement input DIO1 or second measurement input DIO2 and to output a respectively associated detection result which is dependent on the respective measurement potential. Provision is furthermore made for a voltage source having a supply voltage predefined by two supply potentials U and GND. The supply voltage formed of the supply potentials U and GND is applied to a resistor network W.

The first measurement input DIO1 of the first microcontroller C1 is electrically conductively connected to a first tap A1 of the resistor network W, while a second tap A2 of the resistor network W is electrically conductively connected to the second measurement input DIO2 of the first microcontroller C1. The resistor network W includes two current branches connected in parallel between the supply potentials U, GND with switching elements S1 and S2 respectively integrated in the current branch. The switching state thereof, out of at least two switching states, changes from one switching state to the respective other switching state by operation, contact and/or actuation by an operator. Here, for example, the unactuated state is the respectively open state of the switching element S1 and S2. For example, the first switching element S1 and second switching element S2 are each an electromechanical switch or button. The resistor network W is designed such that a different switching potential, at least for each measurement input, is assigned to the respective switching state of the first and second switching element S1, S2. In the closed switching state of the first switching element S1, the resistor R1 is bypassed and the first measurement input DIO1 is set to the supply potential U as the first measurement potential, while in the open switching state of the first switching element S1, the supply potential U reduced by the voltage dropped across the resistor R1 is present as the first measurement potential at the first measurement input DIO1. In the closed switching state of the second switching element S2, the resistor R2 is bypassed and the second measurement input DIO2 is set to the supply potential U as the second measurement potential, while in the open switching state of the second switching element S2, the supply potential U reduced by the voltage dropped across the resistor R2 is present as the second measurement potential at the second measurement input DIO2. The switching potential which is dependent on the switching state of the switching elements S1, S2 is thus respectively present at the first measurement input DIO1 or second measurement input DIO2.

The first microcontroller C1 is designed to detect the switching potentials present at the first measurement input DIO1 or second measurement input DIO2 as operating input of the first switching element S1 or of the second switching element S2 and to transmit said switching potentials to a superordinate microcontroller C2 via a first data bus BUS1.

The second microcontroller C2, superordinate to the first microcontroller C1, is provided and designed to receive the respective detection result from the first microcontroller C1 and to output said detection result to a superordinate control unit U via a second data bus BUS2. Superordinate means that the second microcontroller C2 is not only interposed on the way of the data transmission of the detection result from the first microcontroller C1 to the superordinate control unit U but also decides on the transfer to the superordinate control unit U in dependence on functional monitoring triggered by it.

Provision is additionally made for two active components ES1 and ES2 which are able to be controlled by the first microcontroller C1 via a control line DIO_SS and are integrated into the resistor network W, in order, on the one hand, to respectively apply the measurement potential present at the first measurement input DIO1 and at the second measurement input DIO2 to an interference potential having a predefined time characteristic, preferably different from all the switching potentials due to the respective voltage drop across the resistors R3 or R4, by virtue of a conductive connection of the tap A1 and of the tap A2 via R3 and R4 with the supply potential GND being established, while the switching elements S1 and S2 are each in the open state. The time characteristic of this interference potential is periodic and has a frequency which is higher than a minimum switching frequency which is able to be achieved by manually actuating the switching elements S1 and S2. Here, the active components ES1 and ES2 are each a semiconductor-based switching element, such as a transistor. In this case, the interference potential for the first measurement input DIO1 and the second measurement input DIO2 can be the same or different in terms of absolute value depending on the selection of the resistors R3 or R4. The default relating to the time characteristic of the interference potential is stored in the second microcontroller C2 and is transmitted only to the first microcontroller C1 for controlling the active components ES1 and ES2, while the subsequent comparison of the detection result resulting from the control is transmitted to the second microcontroller C2 after transmission, in order to assume from this, by comparing the two, in the event that the two do not sufficiently correspond to one another, a non-detection of the time characteristic of the interference potential and thus a failure of the first microcontroller C1.

The second microcontroller C2 is designed to at least temporarily prevent a subsequent output of the detection result to the superordinate control unit U if the detection result from the first microcontroller C1 during the control of the active components ES1 and ES2 does not correspond to the predefined time characteristic of the interference potential, for example the frequency thereof being within predefined tolerance limits. Due to the design according to the disclosed embodiments, a failure of the first microcontroller C1, but in particular the event of it being stuck in the detection range, can be reliably detected.

What is claimed is:

1. An operating device, comprising:
a first microcontroller having at least one first measurement input, which is adapted to detect a measurement potential respectively present at the at least one first measurement input and to output a respectively associated detection result which is dependent on the respective measurement potential;
a voltage source having a supply voltage predefined by two supply potentials;
a resistor network to which the supply voltage is applied, wherein the at least one first measurement input is electrically conductively connected to a first tap at the resistor network;
at least one switching element integrated in the resistor network, a switching state of which at least one switching element, out of at least two switching states, is changed by operation by an operator; wherein the resistor network is adapted such that a different switching potential present at the at least one first measurement input is assigned to the respective switching state
a second microcontroller superordinate to the first microcontroller, wherein the second microcontroller is adapted to receive the respective detection result from the first microcontroller and to output said detection result to a superordinate control unit; and
at least one active component which is controlled by the first microcontroller and/or second microcontroller, is integrated into the resistor network and is controlled such that an interference potential having a predefined time characteristic is present as the measurement potential present at the at least one first measurement input;
wherein the second microcontroller is adapted to at least temporarily prevent a subsequent output of the detection result to the superordinate control unit when the detection result from the first microcontroller during the control of the at least one active component does not correspond to the predefined time characteristic of the interference potential.

2. The operating device according to claim 1, wherein the predefined characteristic of the interference potential is periodic and has a frequency which is higher than a minimum switching frequency of the at least one switching element.

3. The operating device according to claim 1, wherein at least the first measurement input of the first microcontroller is adapted as a digital input.

4. The operating device according to claim 1, wherein the first microcontroller has a second measurement input which is electrically conductively connected to a second tap (A2), which is different from the first tap, in the resistor network and is adapted to determine the detection result from a difference in potential between the measurement potential respectively present at the first measurement input and the second measurement input.

5. The operating device according to claim 1, having at least two switching elements, the switching states of which, out of the at least two switching states, are changed by an actuation by an operator and the at least two switching elements are integrated in different branches of the resistor network.

6. The operating device according to claim 5, wherein an active component of the at least one active component is provided for each of the at least two switching elements, wherein the active component for each of the at least two switching element are controlled in parallel.

7. The operating device according to claim 1, wherein the at least one active component is a semiconductor-based switching element.

8. The operating device according to claim 1, wherein a first switching element of the at least one switching element is in an open state while the interference potential having the predefined time characteristic is present at the first measurement input of the first microcontroller.

9. The operating device according to claim 1, wherein the second microcontroller is adapted to report a fault to the superordinate control unit.

10. A motor vehicle, comprising:
an operating device, wherein the operating device comprises:
a first microcontroller having at least one first measurement input, which is adapted to detect a measurement potential respectively present at the at least one first measurement input and to output a respectively associated detection result which is dependent on the respective measurement potential;
a voltage source having a supply voltage predefined by two supply potentials;
a resistor network to which the supply voltage is applied, wherein the at least one first measurement input is electrically conductively connected to a first tap at the resistor network;
at least one switching element integrated in the resistor network, a switching state of which at least one switching element, out of at least two switching states, is changed by operation by an operator; wherein the resistor network is adapted such that a different switching potential present at the at least one first measurement input is assigned to the respective switching state
a second microcontroller superordinate to the first microcontroller, wherein the second microcontroller is adapted to receive the respective detection result from the first microcontroller and to output said detection result to a superordinate control unit; and
at least one active component which is controlled by the first microcontroller and/or second microcontroller, is integrated into the resistor network and is controlled such that an interference potential having a predefined time characteristic is present as the measurement potential present at the at least one first measurement input;
wherein the second microcontroller is adapted to at least temporarily prevent a subsequent output of the detection result to the superordinate control unit when the detection result from the first microcontroller during the control of the at least one active component does not correspond to the predefined time characteristic of the interference potential;
wherein the operating device provides functional monitoring of a safety-relevant switching-state detection.

11. A method for the functional monitoring of switching-state detection, comprising:
providing an operating device, wherein the operating device comprises:
a first microcontroller having at least one first measurement input, which is adapted to detect a measurement potential respectively present at the at least one first measurement input and to output a respectively associated detection result which is dependent on the respective measurement potential;
a voltage source having a supply voltage predefined by two supply potentials;
a resistor network to which the supply voltage is applied, wherein the at least one first measurement input is electrically conductively connected to a first tap at the resistor network;
at least one switching element integrated in the resistor network, a switching state of which at least one switching element, out of at least two switching states, is changed by operation by an operator; wherein the resistor network is adapted such that a different switching potential present at the at least one first measurement input is assigned to the respective switching state
a second microcontroller superordinate to the first microcontroller, wherein the second microcontroller is adapted to receive the respective detection result from the first microcontroller and to output said detection result to a superordinate control unit; and
at least one active component which is controlled by the first microcontroller and/or second microcontroller, is integrated into the resistor network and is controlled such that an interference potential having a predefined time characteristic is present as the measurement potential present at the at least one first measurement input;
wherein the second microcontroller is adapted to at least temporarily prevent a subsequent output of the detection result to the superordinate control unit when the detection result from the first microcontroller during the control of the at least one active component does not correspond to the predefined time characteristic of the interference potential;
controlling the active component such that an interference potential having the predefined time characteristic is present as the measurement potential present at the first measurement input;
preventing an output of the detection result from the second microcontroller to the superordinate control unit when the detection result from the first microcontroller during the control of the active component by the first microcontroller effected by the first microcontroller and/or second microcontroller does not correspond to the predefined characteristic of the interference potential.

12. The operating device according to claim 1, wherein at least one switching potential differs from the two supply potentials.
